(19) United States
(12) Patent Application Publication
(10) Pub. No.: US 2024/0030085 A1
(43) Pub. Date: Jan. 25, 2024

(54) SEMICONDUCTOR MODULE AND METHOD OF MANUFACTURING THE SAME

(71) Applicant: Mitsubishi Electric Corporation, Tokyo (JP)

(72) Inventor: Hongbo ZHANG, Tokyo (JP)

(73) Assignee: Mitsubishi Electric Corporation, Tokyo (JP)

(21) Appl. No.: 18/065,509

(22) Filed: Dec. 13, 2022

(30) Foreign Application Priority Data
Jul. 19, 2022 (JP) 2022-115076

(51) Int. Cl. H01L 23/367; H01L 23/31; H01L 23/495; H01L 23/16; H01L 21/56

(52) U.S. Cl. CPC H01L 23/367; H01L 23/3107; H01L 23/49568; H01L 23/16; H01L 21/565; H01L 24/48

(57) ABSTRACT

A semiconductor module includes: a frame part; a semiconductor device mounted on an upper surface of the frame part; a heat sink joined to a lower surface of the frame part; an insulation sheet provided on a lower surface of the heat sink; and a sealing member sealing the frame part, the semiconductor device, and the heat sink to form a module body, wherein a thickness of the heat sink is equal to or larger than 50% of a thickness of the module body.

### BACKGROUND OF THE INVENTION

### Field

The present disclosure relates to a semiconductor module and a method of manufacturing the same.

### Background

A transfer-mold power module using an insulation sheet made of a resin composite having high heat-releasing performance is used in a wide range of fields such as home appliances. A semiconductor device is mounted on the upper surface of a frame part, and a heat sink is provided at the lower surface of the frame part to improve the heat-releasing performance. The insulation sheet is provided to insulate any electric power circuit inside the module from the outside.

Conventionally, the insulation sheet has been positioned between the frame part and the heat sink. However, the insulation sheet is adjacent to the semiconductor device as a heat generating source, and thus the insulation sheet has needed to have high thermal resistance. In another disclosed configuration, the insulation sheet is provided at the lower surface of the heat sink (refer to JP 2016-092184 A, for example), but temperature increase of the insulation sheet could not be sufficiently reduced with this configuration only.

### SUMMARY

In order to obtain an insulation sheet of high thermal resistance, it is necessary to adjust the content rate of a filler or change a resin material. With such change, the insulation sheet becomes expensive and thus manufacturing cost increases, which has been a problem.

The present disclosure is intended to solve the above-described problem and obtain a semiconductor module for which manufacturing cost can be reduced and a method of manufacturing the same.

A semiconductor module according to the present disclosure includes: a frame part; a semiconductor device mounted on an upper surface of the frame part; a heat sink joined to a lower surface of the frame part; an insulation sheet provided on a lower surface of the heat sink; and a sealing member sealing the frame part, the semiconductor device, and the heat sink to form a module body, wherein a thickness of the heat sink is equal to or larger than 50% of a thickness of the module body.

A method of manufacturing a semiconductor module according to the present disclosure includes: providing an insulation sheet on a lower surface of a heat sink; placing the heat sink and the insulation sheet in a first mold and sealing the heat sink and the insulation sheet with a first sealing member to form a module lower part; placing a frame part on an upper surface of the heat sink exposed without the first sealing member; mounting a semiconductor device on an upper surface of the frame part; and placing the module lower part, the frame part, and the semiconductor device in a second mold and sealing the frame part and the semiconductor device with a second sealing member to form a module upper part.

In the semiconductor module according to the present disclosure, an insulation sheet is provided on a lower surface of the heat sink, and a thickness of the heat sink is equal to or larger than 50% of a thickness of the module body. The insulation sheet is sufficiently separated from the semiconductor device as heat generating source, and thus heat breakdown of the insulation sheet can be prevented. Therefore, no insulation sheet having high thermal resistance is required, and thus manufacturing cost can be reduced.

In the method of manufacturing the semiconductor module according to the present disclosure, the module lower part and the module upper part are separately subjected to mold shaping. Accordingly, the resin material and the mold shaping condition can be individually selected for each of the sealing members. As a result, a manufacturing process can be simplified, and thus manufacturing cost can be reduced.

Other and further objects, features and advantages of the invention will appear more fully from the following description.

### BRIEF DESCRIPTION OF DRAWINGS

FIG. 1 is a cross-sectional view illustrating a semiconductor module according to a first embodiment.

FIG. 2 is a cross-sectional view illustrating a semiconductor module according to the comparative example.

FIG. 3 is a diagram illustrating the relation between the ratio of the thickness of the heat sink relative to the thickness of the module body and the temperature of the insulation sheet.

FIG. 4 is a cross-sectional view illustrating a semiconductor module according to a second embodiment.

FIG. 5 is a cross-sectional view illustrating a method of manufacturing the semiconductor module according to the second embodiment.

FIG. 6 is a cross-sectional view illustrating a method of manufacturing the semiconductor module according to the second embodiment.

FIG. 7 is a cross-sectional view illustrating a method of manufacturing the semiconductor module according to the second embodiment.

FIG. 8 is a cross-sectional view illustrating a method of manufacturing the semiconductor module according to the second embodiment.

FIG. 9 is a cross-sectional view illustrating a method of manufacturing the semiconductor module according to the second embodiment.

### DESCRIPTION OF EMBODIMENTS

A semiconductor module and a method of manufacturing the same according to the embodiments of the present disclosure will be described with reference to the drawings. The same components will be denoted by the same symbols, and the repeated description thereof may be omitted.

### First Embodiment

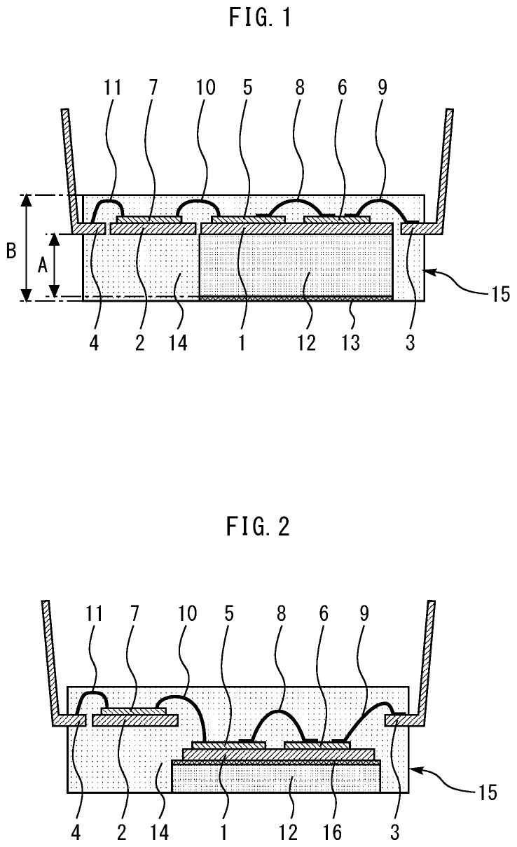

FIG. 1 is a cross-sectional view illustrating a semiconductor module according to a first embodiment. Frame parts 1 and 2 and terminals 3 and 4 are provided at the same height and separated from one another. Semiconductor devices 5 and 6 are mounted on the upper surface of the frame part 1. For example, the semiconductor device 5 is an IGBT, and the semiconductor device 6 is a diode. A control element 7 is mounted on the frame part 2.

Upper-surface electrodes of the semiconductor devices 5 and 6 are connected to each other through a wire 8. The upper-surface electrode of the semiconductor device 6 is connected to one end of the terminal 3 through a wire 9. A control electrode of the semiconductor device 5 is connected to the control element 7 through a wire 10. The control element 7 and one end of the terminal 4 are connected to each other by a wire 11. The control element 7 drives the semiconductor device 5 in accordance with a signal input through the terminal 4, and output signals from the semiconductor devices 5 and 6 are output through the terminal 3.

A heat sink 12 is joined to the lower surface of the frame part 1. An insulation sheet 13 is provided on the lower surface of the heat sink 12. The insulation sheet 13 is made of a composite of epoxy resin and a filler. The filler is ceramic additive particles.

A sealing member 14 seals the frame part 1, the semiconductor devices 5 and 6, and the heat sink 12, thereby forming a module body 15. The sealing member 14 is made of epoxy resin or the like. The other end of each of the terminals 3 and 4 protrudes from a side surface of the module body 15. The lower surface of the insulation sheet 13 is exposed on the lower surface of the module body 15 without the sealing member 14. Copper foil or the like may be provided on the lower surface of the insulation sheet 13. The lower surface of the module body 15 serves as a heat-releasing surface. The heat-releasing surface is bonded to an external heat-releasing fin by a grease material.

Effects of the present embodiment will be described below in comparison with a comparative example. FIG. 2 is a cross-sectional view illustrating a semiconductor module according to the comparative example. In the comparative example, an insulation sheet 16 is positioned between the frame part 1 and the heat sink 12. Since the insulation sheet 16 is adjacent to the semiconductor devices as heat generating sources, the insulation sheet 16 is exposed to a high temperature at a substantially same level as the highest temperature of the semiconductor devices 5 and 6. Thus, the insulation sheet 16 needs to have high thermal resistance, and accordingly, manufacturing cost increases. In recent practical application of a SiC device, an insulation sheet having high thermal resistance is needed for the structure of the comparative example. However, since the glass transition temperature of a resin composite of the insulation sheet 16 is typically 160 to 170° C., sufficient improvement of thermal resistance is difficult in terms of technology and cost. However, in the present embodiment, since the insulation sheet 13 is provided on the lower surface of the heat sink 12, the insulation sheet 13 can be separated from the semiconductor devices 5 and 6 as heat generating sources.

In the comparative example, the frame part 1 corresponds to one tenth of heat resistance on a main heat-releasing path at the lower surface side of the module, and the insulation sheet 16 corresponds to nine tenths thereof. However, in the present embodiment, the frame part 1 corresponds to one tenth of heat resistance on the main heat-releasing path, the heat sink 12 corresponds to three tenths thereof, and the insulation sheet 13 corresponds to six tenths thereof. Thus, in the present embodiment, the ratio corresponding to the insulation sheet 13 in heat resistance on the main heat-releasing path can be reduced.

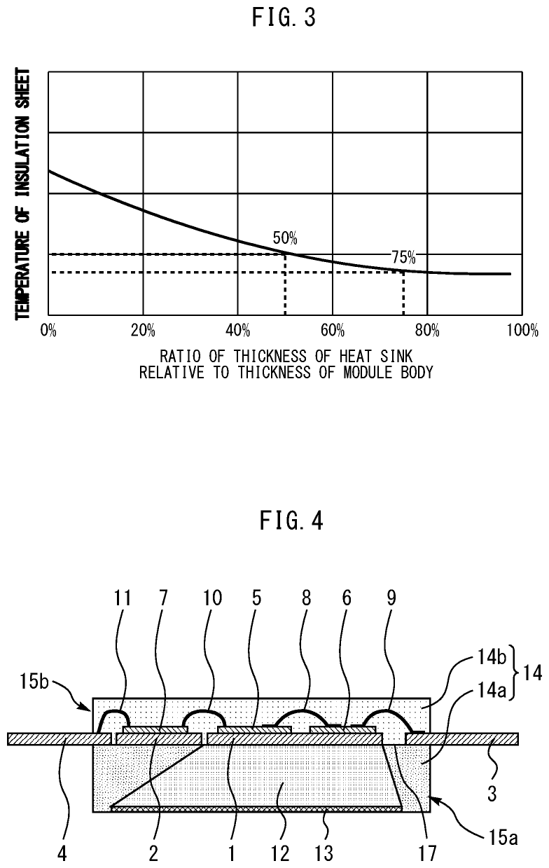

FIG. 3 is a diagram illustrating the relation between the ratio of the thickness of the heat sink relative to the thickness of the module body and the temperature of the insulation sheet. Heat resistance is estimated based on the thermal conductivity of the material of any layer between each of the semiconductor devices 5 and 6 as heat generating sources and the insulation sheet 13 and the thickness of the layer in the longitudinal direction, and the temperature of the insulation sheet 13 is calculated. In a region where the ratio A/B of the thickness A of the heat sink 12 relative to the thickness B of the module body 15 is smaller than 50%, the temperature of the insulation sheet 13 significantly decreases as the thickness A of the heat sink 12 increases. When the ratio A/B is equal to or larger than 50%, the decrease of the temperature of the insulation sheet 13 decelerates. When the ratio A/B reaches 75%, the decrease of the temperature of the insulation sheet 13 saturates.

Thus, in the present embodiment, the thickness A of the heat sink 12 is equal to or larger than 50% of the thickness B of the module body 15 (A/B≥0.50), preferably equal to or larger than 75% (A/B≥0.75). In other words, the insulation sheet 13 is sufficiently separated from the semiconductor devices 5 and 6 as heat generating sources to intentionally increase heat resistance on a heat transfer path between the sheet and each device. Accordingly, the ambient temperature of the insulation sheet 13 decreases, and heat breakdown of the insulation sheet 13 can be prevented. Thus, no insulation sheet having high thermal resistance is required, and thus manufacturing cost can be reduced. Moreover, power devices having a higher operation temperature can be mounted as the semiconductor devices 5 and 6.

Heat flow from the semiconductor devices 5 and 6 is thermally diffused at the heat sink 12 having a large heat capacity. In this case, transitional heat is equalized and discharged from the heat-releasing surface. In this manner, the heat flow is temporarily accumulated in the thick heat sink 12 before being externally discharged, and accordingly, the ambient temperature of the insulation sheet 13 according to the present embodiment, which is provided on the lower surface of the heat sink 12, is lower than the ambient temperature of the insulation sheet 16 according to the comparative example, which is provided directly below the semiconductor devices 5 and 6, by 20° C. to 30° C. approximately. However, the temperature difference between the insulation sheets differs depending on an operation condition and the like.

Furthermore, in the comparative example, since the height of the frame part 1 is lower than the heights of the frame part 2 and the terminals 3 and 4, the sealing member 14 above the frame part 1 is thick. Accordingly, heat resistance from the semiconductor devices 5 and 6 mounted on the frame part 1 to the upper surface of the module is more than 10 times higher than heat resistance on a heat-releasing path on the lower surface side of the module, and thus the upper surface side of the module hardly serves as a heat-releasing path.

However, in the present embodiment, the terminals 3 and 4 and the frame parts 1 and 2 are at the same height. Accordingly, the sealing member 14 above the frame part 1 is thin, and heat resistance from the semiconductor devices 5 and 6 to the upper surface of the module can be reduced. As a result, heat-releasing performance of the entire module can be improved. Moreover, since the height of the frame part 1 is high, the configuration is effective for separation of the insulation sheet 13 from the semiconductor devices 5 and 6 as heat generating sources.

The material of the heat sink 12 is aluminum in terms of cost and workability. The material of the frame part 1 is, for example, copper. Accordingly, the thermal conductivity of the heat sink 12 is lower than the thermal conductivity of the frame part 1. Heat resistance R [m²·K/W] is obtained by R=d/λ where d and λ represent the thickness [m] and thermal conductivity [W/(m·k)] of a heat insulation material, respectively. Thus, heat resistance between each of the semiconductor devices 5 and 6 as heat generating sources and the insulation sheet 13 is high, and as a result, the ambient temperature of the insulation sheet 13 can be reduced. The material of the heat sink 12 is preferably an alloy material having a lower thermal conductivity than aluminum.

### Second Embodiment

FIG. 4 is a cross-sectional view illustrating a semiconductor module according to a second embodiment. The sealing member 14 includes a first sealing member 14a provided on the lower surface side of the frame part 1, and a second sealing member 14b provided on the upper surface side of the frame part 1. A junction interface 17 exists between the first sealing member 14a and the second sealing member 14b. The first sealing member 14a and the second sealing member 14b are directly joined to each other through the junction interface 17. The junction interface 17 can be visually recognized or checked by analysis. The first sealing member 14a and the second sealing member 14b may be made of the same material or different materials.

The first sealing member 14a covers the side surfaces of the heat sink 12 and the insulation sheet 13. The upper surface of the heat sink 12 is exposed without the first sealing member 14a and flush with the upper surface of the first sealing member 14a. The second sealing member 14b covers the upper and side surfaces of the frame parts 1 and 2 and the terminals 3 and 4, the semiconductor devices 5 and 6, the control element 7, and the wires 8 to 11. The lower surface of the second sealing member 14b is flush with the lower surfaces of the frame parts 1 and 2 and the terminals 3 and 4. The lower surface of the frame part 1 is exposed without the second sealing member 14b and contacts the upper surface of the heat sink 12.

The heat sink 12 has a trapezoid section in which the bottom side closer to the insulation sheet 13 is longer than the top side closer to the frame part 1. Thus, the area of the upper surface of the heat sink 12, which receives heat from the semiconductor devices 5 and 6 as heat sources, is smaller than the area of the lower surface of the heat sink 12, which discharges heat to the external heat-releasing fin. Accordingly, heat resistance between each of the semiconductor devices 5 and 6 and the insulation sheet 13 can be further increased, and increase of the ambient temperature of the insulation sheet 13 can be further reduced. Moreover, heat is diffused to the entire heat sink 12, and thus the size of the heat sink 12 can be reduced. The other configuration is the same as in the first embodiment.

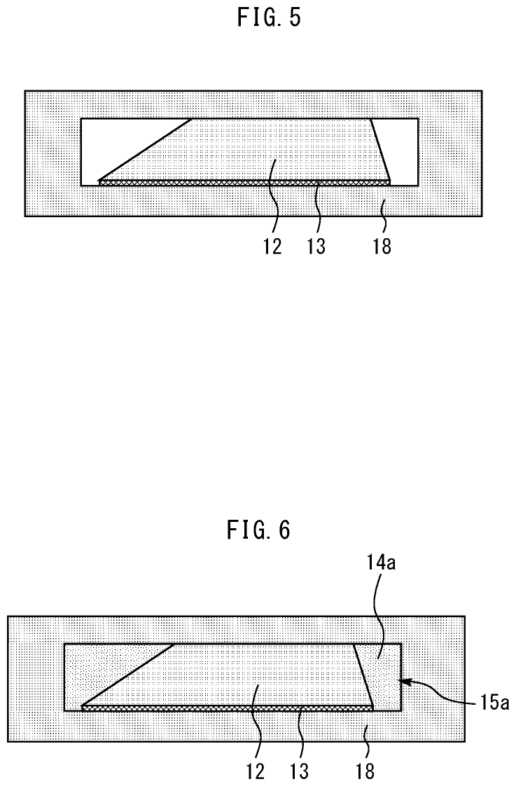

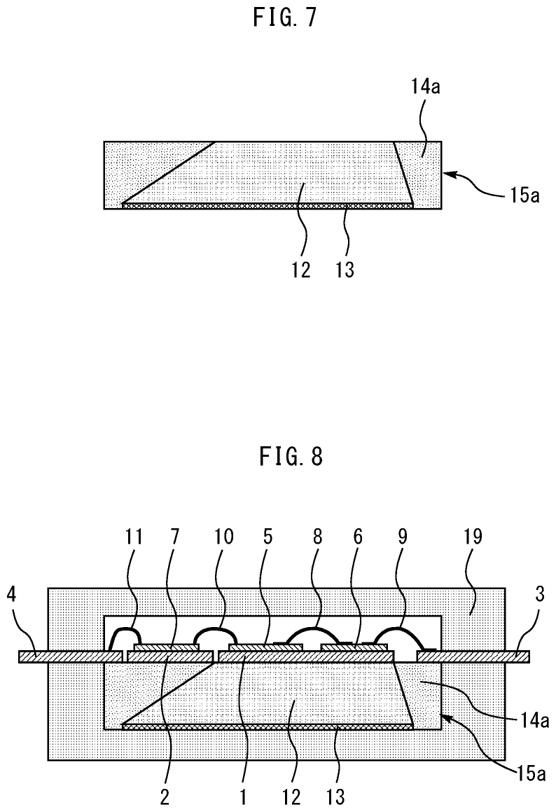

FIGS. 5 to 9 are cross-sectional views illustrating a method of manufacturing the semiconductor module according to the second embodiment. First, the insulation sheet 13 is provided on the lower surface of the heat sink 12 as illustrated in FIG. 5. The heat sink 12 and the insulation sheet 13 are placed in a first mold 18. Subsequently, as illustrated in FIG. 6, the first sealing member 14a is injected into the first mold 18 to seal the heat sink 12 and the insulation sheet 13 with the first sealing member 14a, thereby shaping a module lower part 15a. As illustrated in FIG. 7, the upper surface of the module lower part 15a is flat, and the upper surface of the first sealing member 14a is flush with the upper surface of the heat sink 12.

Subsequently, as illustrated in FIG. 8, the frame parts 1 and 2 and the terminals 3 and 4 are placed at the same height on the upper surface of the module lower part 15a. In particular, the frame part 1 is placed on the upper surface of the heat sink 12 exposed without the first sealing member 14a. The semiconductor devices 5 and 6 are mounted on the upper surface of the frame part 1. The semiconductor devices 5 and 6 are connected to the terminals 3 and 4 through wires. The module lower part 15a, the frame parts 1 and 2, parts of the terminals 3 and 4, and the semiconductor devices 5 and 6 are placed in a second mold 19.

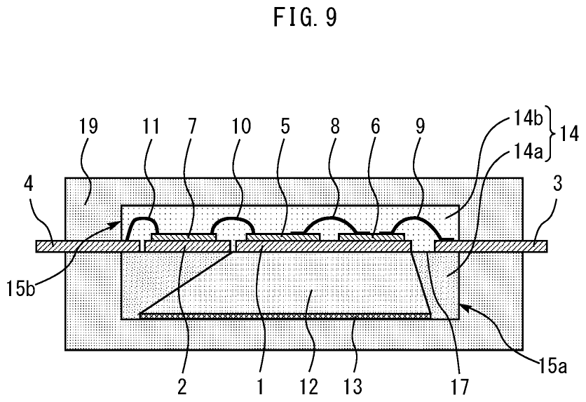

Subsequently, as illustrated in FIG. 9, the second sealing member 14b is injected into the second mold 19 to seal the frame parts 1 and 2 and the semiconductor devices 5 and 6 with the second sealing member 14b, thereby shaping a module upper part 15b. Through the above-described processes, the semiconductor module according to the present embodiment is manufactured.

In a conventional case, mold shaping is performed all at once after any chip is mounted on a frame part and bonded to a wire. An insulation sheet is bonded to the frame part by temperature and pressure of resin curing at the mold shaping.

However, in the present embodiment, the module lower part 15a and the module upper part 15b are separately subjected to mold shaping. Thus, a resin material or a mold shaping condition may differ between the first sealing member 14a and the second sealing member 14b. Accordingly, the resin material and the mold shaping condition can be individually selected for each of the sealing members. As a result, a manufacturing process can be simplified, and thus manufacturing cost can be reduced. Moreover, process designing can be optimized for the shaping process of each of the module lower part 15a and the module upper part 15b, which improves manufacturing quality.

The upper surface of the module lower part 15a is preferably flat. With this configuration, the frame parts 1 and 2 and the terminals 3 and 4 can be placed at the same height on the upper surface of the module lower part 15a. Similarly to the first embodiment, the thickness of the heat sink 12 is equal to or larger than 50% of the total thickness of the module lower part 15a and the module upper part 15b, but is preferably equal to or larger than 75%. Accordingly, the same effects as in the first embodiment can be obtained. The manufacturing method according to the present embodiment is also applicable to a case in which the heat sink 12 has a rectangular section as in the first embodiment.

The semiconductor devices 5 and 6 are not limited to semiconductor devices formed of silicon, but instead may be formed of a wide-bandgap semiconductor having a bandgap wider than that of silicon. The wide-bandgap semiconductor is, for example, a silicon carbide, a gallium-nitride-based material, or diamond. A semiconductor device formed of such a wide-bandgap semiconductor has a high voltage resistance and a high allowable current density, and thus can be miniaturized. The use of such a miniaturized semiconductor device enables the miniaturization and high integration of the semiconductor apparatus in which the semiconductor device is incorporated. Further, since the semiconductor device has a high heat resistance, a radiation fin of a heatsink can be miniaturized and a water-cooled part can be air-cooled, which leads to further miniaturization of the semiconductor apparatus. Further, since the semiconductor device has a low power loss and a high efficiency, a highly efficient semiconductor apparatus can be achieved.

Although the preferred embodiments and the like have been described in detail above, the present disclosure is not limited to the above-described embodiments and the like, but the above-described embodiments and the like can be subjected to various modifications and replacements without departing from the scope described in the claims. Aspects of the present disclosure will be collectively described as supplementary notes.

### (Supplementary Note 1)

A semiconductor module comprising:
a frame part;
a semiconductor device mounted on an upper surface of the frame part;
a heat sink joined to a lower surface of the frame part;
an insulation sheet provided on a lower surface of the heat sink; and
a sealing member sealing the frame part, the semiconductor device, and the heat sink to form a module body,
wherein a thickness of the heat sink is equal to or larger than 50% of a thickness of the module body.

### (Supplementary Note 2)

The semiconductor module according to Supplementary Note 1, wherein a thickness of the heat sink is equal to or larger than 75% of a thickness of the module body.

### (Supplementary Note 3)

The semiconductor module according to Supplementary Note for 2, wherein the sealing member includes a first sealing member provided on a lower surface side of the frame part, and a second sealing member provided on an upper surface side of the frame part, and
a junction interface exists between the first sealing member and the second sealing member.

### (Supplementary Note 4)

The semiconductor module according to any one of Supplementary Notes 1 to 3, further comprising a terminal including one end connected to the semiconductor device and the other end protruding from a side surface of the sealing member,
wherein the terminal and the frame part are at the same height.

### (Supplementary Note 5)

The semiconductor module according to any one of Supplementary Notes 1 to 4, wherein the heat sink has a trapezoid section in which a bottom side closer to the insulation sheet is longer than a top side closer to the frame part.

### (Supplementary Note 6)

The semiconductor module according to any one of Supplementary Notes 1 to 5, wherein thermal conductivity of the heat sink is lower than thermal conductivity of the frame part.

### (Supplementary Note 7)

The semiconductor module according to any one of Supplementary Notes 1 to 6, wherein the insulation sheet is made of a composite of resin and a filler.

### (Supplementary Note 8)

The semiconductor module according to any one of Supplementary Notes 1 to 7, wherein the semiconductor device is formed of a wide-bandgap semiconductor.

### (Supplementary Note 9)

A method of manufacturing a semiconductor module comprising:
providing an insulation sheet on a lower surface of the heat sink;
placing the heat sink and the insulation sheet in a first mold and sealing the heat sink and the insulation sheet with a first sealing member to form a module lower part;
placing a frame part on an upper surface of the heat sink exposed without the first sealing member;
mounting a semiconductor device on an upper surface of the frame part; and
placing the module lower part, the frame part, and the semiconductor device in a second mold and sealing the frame part and the semiconductor device with a second sealing member to form a module upper part.

### (Supplementary Note 10)

The method of manufacturing a semiconductor module according to Supplementary Note 9, wherein a resin material or a mold shaping condition is differ between the first sealing member and the second sealing member.

### (Supplementary Note 11)

The method of manufacturing a semiconductor module according to Supplementary Note 9 or 10, wherein an upper surface of the module lower part is flat,
the frame part and a terminal are placed on an upper surface of the module lower part, and
the semiconductor device is connected to the terminal through a wire and sealed with a second sealing member.

### (Supplementary Note 12)

The method of manufacturing a semiconductor module according to any one of Supplementary Notes 9 to 11, wherein a thickness of the heat sink is equal to or larger than 50% of a total thickness of the module lower part and the module upper part.

### (Supplementary Note 13)

The method of manufacturing a semiconductor module according to any one of Supplementary Notes 9 to 11, wherein a thickness of the heat sink is equal to or larger than 75% of a total thickness of the module lower part and the module upper part.

Obviously many modifications and variations of the present disclosure are possible in the light of the above teachings. It is therefore to be understood that within the scope of the appended claims the invention may be practiced otherwise than as specifically described. The entire disclosure of Japanese Patent Application No. 2022-115076, filed on Jul. 19, 2022 including specification, claims, drawings and summary, on which the convention priority of the present application is based, is incorporated herein by reference in its entirety.

1. A semiconductor module comprising:
a frame part;
a semiconductor device mounted on an upper surface of the frame part;
a heat sink joined to a lower surface of the frame part;
an insulation sheet provided on a lower surface of the heat sink; and
a sealing member sealing the frame part, the semiconductor device, and the heat sink to form a module body,
wherein a thickness of the heat sink is equal to or larger than 50% of a thickness of the module body.

2. The semiconductor module according to claim 1, wherein the thickness of the heat sink is equal to or larger than 75% of the thickness of the module body.

3. The semiconductor module according to claim 1, wherein the sealing member includes a first sealing member provided on a lower surface side of the frame part, and a second sealing member provided on an upper surface side of the frame part, and
a junction interface exists between the first sealing member and the second sealing member.

4. The semiconductor module according to claim 1, further comprising a terminal including one end connected to the semiconductor device and the other end protruding from a side surface of the sealing member,
wherein the terminal and the frame part are at the same height.

5. The semiconductor module according to claim 1, wherein the heat sink has a trapezoid section in which a bottom side closer to the insulation sheet is longer than a top side closer to the frame part.

6. The semiconductor module according to claim 1, wherein thermal conductivity of the heat sink is lower than thermal conductivity of the frame part.

7. The semiconductor module according to claim 1, wherein the insulation sheet is made of a composite of resin and a filler.

8. The semiconductor module according to claim 1, wherein the semiconductor device is formed of a wide-bandgap semiconductor.

9. A method of manufacturing a semiconductor module comprising:
providing an insulation sheet on a lower surface of a heat sink;
placing the heat sink and the insulation sheet in a first mold and sealing the heat sink and the insulation sheet with a first sealing member to form a module lower part;
placing a frame part on an upper surface of the heat sink exposed without the first sealing member;
mounting a semiconductor device on an upper surface of the frame part; and
placing the module lower part, the frame part, and the semiconductor device in a second mold and sealing the frame part and the semiconductor device with a second sealing member to form a module upper part.

10. The method of manufacturing a semiconductor module according to claim 9, wherein a resin material or a mold shaping condition is differ between the first sealing member and the second sealing member.

11. The method of manufacturing a semiconductor module according to claim 9, wherein an upper surface of the module lower part is flat,
the frame part and a terminal are placed on an upper surface of the module lower part, and
the semiconductor device is connected to the terminal through a wire and sealed with a second sealing member.

12. The method of manufacturing a semiconductor module according to claim 9, wherein a thickness of the heat sink is equal to or larger than 50% of a total thickness of the module lower part and the module upper part.

13. The method of manufacturing a semiconductor module according to claim 9, wherein a thickness of the heat sink is equal to or larger than 75% of a total thickness of the module lower part and the module upper part.
